(19) United States
(12) Patent Application Publication
(10) Pub. No.: US 2026/0118398 A1
(43) Pub. Date: Apr. 30, 2026

(54) TEST AND/OR MEASUREMENT SYSTEM FOR MEASURING A NOISE FIGURE OF A DUT

(71) Applicant: Rohde & Schwarz GmbH & Co. KG, Munich (DE)

(72) Inventors: Marius HAISCH, Memmingen (DE); Julian HARMS, Munich (DE); Christopher STUMPF, Munich (DE)

(73) Assignee: Rohde & Schwarz GmbH & Co. KG, Munich (DE)

(21) Appl. No.: 18/926,507

(22) Filed: Oct. 25, 2024

(51) Int. Cl. G01R 29/26

(52) U.S. Cl. CPC G01R 29/26

(57) ABSTRACT

The present disclosure relates to a test and/or measurement system for measuring a noise figure of a device-under-test (DUT). The test and/or measurement system comprises: a test port arranged for being connected to a port of the DUT; an interface unit comprising and amplifier; and a first receiver circuit; wherein, if the test and/or measurement system is operated in a noise figure measurement mode, an input port of the amplifier is electrically connected to the test port and an output port of the amplifier is electrically connected to the first receiver circuit; wherein the interface unit further comprises a biasing circuit which is electrically connected to the output port of the amplifier and is configured to provide a biasing current and/or voltage for the amplifier during operation; and wherein the biasing circuit comprises at least one gyrator circuit.

### TECHNICAL FIELD

The disclosure relates to a test and/or measurement system, such as a vector network analyzer (VNA), for measuring a noise figure of a device-under-test (DUT).

### BACKGROUND ART

A vector network analyzer (short: VNA) is a device that can be used to measure the performance of RF (radio frequency) devices and networks. For instance, VNAs enable the precise analysis of key RF properties, such as impedance, reflection, and transmission, making VNAs essential for designing and testing antennas, filters, amplifiers, and other RF components.

To perform accurate measurements, VNAs usually contain amplifiers which can boost weak signals to ensure they can be accurately processed and measured. These amplifiers are usually biased, i.e. they receive a constant DC current or voltage via a bias tee circuit with a coil as the reactive element. However, when using a coil as reactive element for biasing, the required inductance and therefore also the size of the coil depend on the lowest operating frequency of the amplifier. When operating at very low frequencies, large coils are required which occupy a large installation space in the VNA. Large coils have the further disadvantage of stronger parasitic effects, which reduces the bandwidth at higher frequencies.

### SUMMARY

Thus, there is a need to provide an improved test and/or measurement system, which avoids the above-mentioned disadvantages.

These and other objectives are achieved by the embodiments provided in the enclosed independent claims. Advantageous implementations of the present disclosure are further defined in the dependent claims.

According to a first aspect, the disclosure relates to a test and/or measurement system for measuring a noise figure of a device-under-test (DUT). The test and/or measurement system comprises: a test port arranged for being connected to a port of the DUT; and an interface unit comprising and amplifier and a first receiver circuit, wherein, if the test and/or measurement system is operated in a noise figure measurement mode, an input port of the amplifier is electrically connected to the test port and an output port of the amplifier is electrically connected to the first receiver circuit. The interface unit further comprises a biasing circuit which is electrically connected to the output port of the amplifier and is configured to provide a biasing current and/or voltage for the amplifier during operation; wherein the biasing circuit comprises at least one gyrator circuit.

This achieves the advantage that a bias circuit for an amplifier can be provided that requires less space, while being operable down to low frequency of 100 MHz or less. Furthermore, the output resistance of the gyrator circuit is much lower than that of a conventional bias tee circuit with a coil and exhibits less parasitic effects.

The test and/or measurement system can be a vector network analyzer. The amplifier can be a linear amplifier and/or a low-noise amplifier (LNA) of the VNA.

The test and/or measurement system can be operable in the noise figure measurement mode and in an S-parameter measurement mode. For instance, in the S-parameter measurement mode, the system can measure S-parameters of the connected DUT. For instance, the test and/or measurement system switches between these modes by connecting different internal components to a signal chain.

In an implementation form, the at least one gyrator circuit is configured to provide an impedance of more than 100 μH, 200 μH, 500 μH, 800 μH, 1 mH, 2 mH, 4 mH, 8 mH, 30 mH, 60 mH, 100 mH, or 200 mH to the output port of the amplifier.

In an implementation form, the gyrator circuit comprises an input port which is configured to receive a DC bias voltage.

In an implementation form, the gyrator circuit is an active gyrator circuit comprising at least one operational amplifier.

In an implementation form, the bias circuit comprises at least one of the following passive elements: an inductance, a capacitance, and a resistance; wherein the at least one passive element is electrically connected between the at least one gyrator circuit and the output port of the amplifier.

In an implementation form, the first receiver circuit comprises at least one of the following elements: an amplifier unit, a filter unit, and a mixing unit.

In an implementation form, the test and/or measurement system further comprises a base unit which comprises a first ADC (analog-to-digital converter) unit, wherein the first ADC unit is electrically connected to the first receiver circuit.

For example, the base unit and the interface unit are arranged in the same housing or in separate housings.

In an implementation form, the test and/or measurement system further comprises a frontend unit, wherein the test port is arranged on the frontend unit.

For example, the frontend unit and the interface unit are arranged in the same housing or in separate housings.

In an implementation form, the interface unit comprises a switching unit which is configured to connect the test port to the amplifier if the test and/or measurement system operates in the noise figure measurement mode. In addition or alternatively, the interface unit may comprise a further switching unit which is configured to connect the amplifier to the first receiver circuit if the test and/or measurement system operates in the noise figure measurement mode.

In an implementation form, the test and/or measurement system further comprises a second receiver circuit; a directive element; and a signal source configured to generate a test signal; wherein the directive element is electrically connected to the switching unit, the signal source, the first receiver circuit and the second receiver circuit, and wherein the test and/or measurement system is operable in an S-parameter measurement mode.

For example, the signal source can be a low frequency signal source.

In an implementation form, if the test and/or measurement system is operated in the S-parameter measurement mode, the switching unit is configured to electrically connect the test port to the directive element; and the directive element is configured to forward the test signal after being transmitted by the DUT and received via the test port to the second or the first receiver circuit.

In an implementation form, if the test and/or measurement system is operated in the S-parameter measurement mode, the switching unit is configured to electrically connect the test port to the directive element; and the directive element is configured to: forward a first part of the test signal to the test port, a second part of the test signal to one of the first or the second receiver circuit, and a reflection of the first part of the test signal from the DUT which is received via the test port to the other one of the first or the second receiver circuit.

For example, the first and the second receiver circuit are arranged in the interface unit.

In an implementation form, the base unit comprises a second ADC unit, wherein the second ADC unit is electrically connected to the second receiver circuit.

### BRIEF DESCRIPTION OF THE DRAWINGS

The above-described aspects and implementation forms of the present disclosure will be explained in the following description of specific embodiments in relation to the enclosed drawings, in which:

FIG. 1 shows a schematic diagram of a test and/or measurement system according to an embodiment;

FIG. 2 shows a schematic diagram of a biasing circuit according to an embodiment;

FIG. 3 shows a schematic diagram of a gyrator circuit according to an embodiment; and

FIGS. 4A-4D show exemplary embodiments of an image-free receiver circuit.

### DETAILED DESCRIPTIONS OF EMBODIMENTS

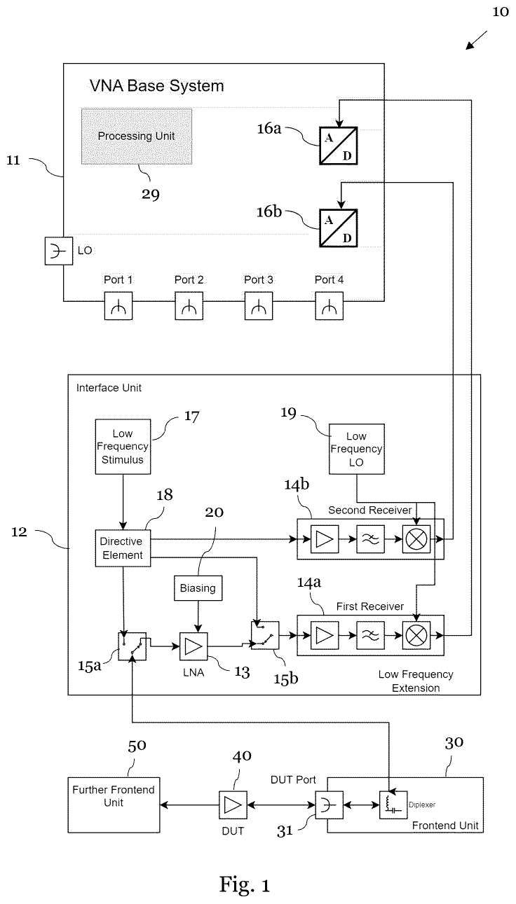

FIG. 1 shows a schematic diagram of a test and/or measurement system 10 for measuring a noise figure of a DUT 40 according to an embodiment.

The test and/or measurement system 10 comprises a test port 31 arranged for being connected to a port of the DUT 40; and an interface unit 12 comprising and amplifier 13 and a first receiver circuit 14a. The test and/or measurement system 10 is operable in a noise figure measurement mode, in which an input port of the amplifier 13 is electrically connected to the test port 31 and an output port of the amplifier 13 is electrically connected to the first receiver circuit 14a. The interface unit 21 further comprises a biasing circuit 20 which is electrically connected to the output port of the amplifier 13 and is configured to provide a biasing current and/or voltage for the amplifier 13 during operation; wherein the biasing circuit 20 comprises at least one gyrator circuit.

The test and/or measurement system 10 can be a vector network analyzer (VNA) or a VNA system. The test port 31 can be a DUT port of the system 10.

The DUT 40 can be an RF device under test, such as an antenna, a filter, an amplifier, or another RF component. The DUT 40 can be a two-port device which can transmit RF signals.

The connections in the system 10 can be direct or indirect connections, i.e., there can be further elements connected between two components that are indirectly connected (e.g., switches, capacitors filters, etc.). Herein, connections between devices and/or components generally refer to electrical connections suitable for transmitting signals.

The amplifier 13 can be a linear amplifier and/or a low-noise amplifier (LNA). The amplifier 13 can have an input port via which it receives a (weak) RF signal, e.g. an AC signal from the DUT, and an output port via which it forwards an amplified version of the RF signal, e.g. to the first receiver circuit 14a. For instance, the bias current and/or voltage is a stable DC current and/or voltage that is provided to the output port of the amplifier 13 to ensure that the amplifier 13 operates correctly and, e.g., exhibits a linear behavior and low distortions over its operating bandwidth. An AC signal, e.g., provided by the DUT 40, can be superposed on this DC bias current and/or voltage.

As shown in FIG. 1, the first receiver circuit 14a (which may also be referred to as first receiver unit) can comprise the following elements: an amplifier unit, a filter unit, and a mixing unit. The mixing unit (or mixer) of the first receiver circuit 14a can be connected to a local oscillator (LO) 19 of the system 10. The LO 19 can be a low frequency LO. The test and/or measurement system 10 can further comprise a first ADC unit 16a (e.g., an ADC) that is electrically connected to the first receiver 14a circuit.

For instance, if the system 10 operates in the noise figure measurement mode, an RF signal received from the DUT 40 can be amplified by the amplifier 13, converted by the first receiver circuit 14a to an IF (intermediate frequency) signal via its mixing unit and subsequently digitalized by the first ADC unit 16a. The digitalized signal can then be analyzed by an internal processor 29, e.g. a microprocessor or an ASIC, of the system 10 to determine a noise figure of the DUT 40. The mixing unit could also be bypassed if not required, e.g. if the LO signal is zero, such that the IF signal corresponds to the RF signal.

The noise figure (short: NF) is a figure of merit that indicates the noise introduced by a two-port component in a signal chain. For instance, the noise figure can be determined as the ratio of an input signal-to-noise ratio (SNR) to an output SNR of the two-port component.

The first ADC unit 16a and/or the internal processing unit can be arranged in a base unit 11 of the test and/or measurement system 10. The base unit 11 can be a base system or a base module. The base unit 11 can comprise additional ports, e.g. test ports 1 to 4 and/or a LO signal port.

The base unit 11 and the interface unit 12 can be arranged in the same housing, e.g. in a common housing of the VNA. Alternatively, the base unit 11 and the interface unit 12 could be arranged in separate housings. In the former case, the interface unit 12 can be an internal circuit (i.e., an interface circuit) of the base unit 11.

The test and/or measurement system 10 may further comprise a frontend unit 30, wherein the test port 31 which is connectable to the DUT 40 is arranged on the frontend unit 30. The frontend unit 30 can be configured to forward an RF signal received from the DUT 40 to the interface unit 12. For instance, the frontend unit 30 can comprise elements, such as a diplexer, to adapt and/or process a received RF signal.

The frontend unit 30 and the interface unit 12 can be arranged in the same housing or in separate housing. For instance, both the interface unit 12 and the frontend unit 30 could be arranged in a housing of the base unit 11.

If the DUT 40 is a two (or more) port device, it can be connected to a further frontend 50 of the test and/or measurement system 10. Both frontends 30, 50 can forwards and/or receive RF signals to respectively from the DUT 40.

The interface unit 12 may comprise switching units 15a, 15b which are configured to connect the input port of the amplifier 13 to the test port 31 and the output port of the amplifier to the first receiver circuit 14a if the test and/or measurement system 10 operates in the noise figure measurement mode. Each of the switching units 15a, 15b can be formed by a controllable switch.

The exemplary test and/or measurement system 10 shown in FIG. 1 can further be operated in an S-parameter measurement mode. In this further mode, S-parameters of the DUT 40 can be measured. For example, the test-and/or measurement system is configured to be either operated in the noise figure measurement mode or in the S-parameter measurement mode.

To carry out S-parameter measurements, the system 10 may comprise a second receiver circuit 14b; a directive element 18; and a signal source 17 configured to generate a test signal, e.g. in the form of a low frequency stimulus signal. The directive element 18 can comprise a directional coupler and/or a bridge directive element which can be a single element or a plurality of elements comprising (but not limited to) switches and couplers.

For example, if the test and/or measurement system 10 is operated in the S-parameter measurement mode: a) the switching unit 15a is configured to electrically connect the test port 31 to the directive element 18; and b) the directive element 18 is configured to forward a test signal which was transmitted by the DUT 40 and which is received via the test port 31 to the first or the second receiver circuit 14a, 14b. Therefore, the further switching unit 15b can connect the directive element 18 to the first receiver circuit 14. The first or the second receiver circuit 14a, 14b can convert the thus received test signal to an IF signal and forward said signal to the first ADC unit 16a or to a second ADC unit 16b of the base unit 11. The test signal can be a signal which is generated by the signal source 17 (or another RF source), transmitted by the DUT 40 and received via the test port 31.

In addition or alternatively, if the test and/or measurement system 10 is operated in the S-parameter measurement mode: a) the switching units 15a, 15b are configured to connect the directive element 18 to the test port 31 and to the first receiver circuit 14a; and b) the directive element 18 is configured to: i) forward a first part of the test signal generated by the signal source 17 to the test port 31; ii) forward second part of the generated test signal to one of the first or the second receiver unit 14a, 14b; and iii) forward a reflection of the first part of the test signal from the DUT 40 which is received via the test port 31 to the other one of the first or the second receiver unit 14a, 14b. In other words: a test signal is generated by the signal source 17, a part of this test signal is forwarded to the DUT and a further part is coupled out and fed to one of the first or the second receiver circuit 14a, 14b, wherein a further part of the test signal that is reflected by the DUT 40 is fed to the other one of the receiver circuits 14a, 14b for further processing.

For example, the first and the second receiver circuit 14a, 14b can be essentially identical, i.e. contain the same elements (e.g., an amplifier unit, a filter unit and mixing unit), and can both be arranged in the interface unit 12. Their output can be electrically connected to a respective ADC unit 16a, 16b in the base unit 11, where it can be digitalized and processed by the processing unit, e.g., for calculating the S-parameters.

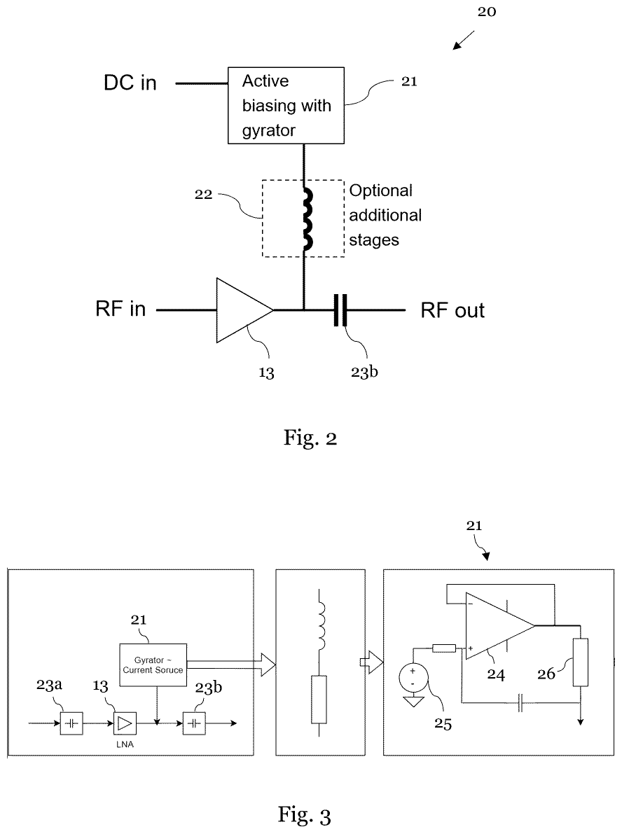

FIG. 2 shows a schematic diagram of the biasing circuit 20 according to an embodiment. The biasing circuit 20 is used for providing the bias current and/or voltage to the amplifier 13, in particular during the noise figure measurement mode.

The biasing circuit 20 comprises the gyrator circuit 21 (also referred to as: gyrator unit) which can comprise an input port for receiving a DC bias voltage. The bias current and/or voltage which is provided to the output port of the amplifier 13 by the bias circuit 20 can be generated by the gyrator circuit 21 based on said DC bias voltage.

The gyrator circuit 21 can provide an impedance of more than 100 μH, 200μH, 500 μH, 800 μH, 1 mH, 2 mH, 4 mH, 8 mH, 30 mH, 60 mH, 100 mH, or 200 mH to the output port of the amplifier 13.

Besides the gyrator circuit 21, the biasing circuit 20 can comprise at least one passive element 22 or stage. The passive element 22 can be electrically connected between the gyrator circuit 21 and the output port of the amplifier 13. In FIG. 2, the passive element 22 is an inductance. However, the passive elements may also comprise a capacitance and/or a resistance.

FIG. 3 shows a schematic diagram of the gyrator circuit 21 according to an embodiment.

As shown in the left image of FIG. 3, the gyrator circuit 21 can be connected to an output port (or output terminal) of the amplifier 13, e.g., between the output port of the amplifier 13 and a capacitor 23b. A further capacitor 23a can be connected in front of the amplifier. The center image of FIG. 3 shows an equivalent circuit of the gyrator circuit 21 which indicates electrical characteristics of the gyrator circuit 21. The right image of FIG. 3 shows an exemplary circuit structure of the gyrator circuit 21 for biasing the amplifier 13.

The gyrator circuit 21 can be in the form of an active gyrator circuit comprising at least one operational amplifier 24. As shown in FIG. 3 the gyrator circuit 21 can be connected to a DC source 25 for receiving the DC bias signal. Further, the gyrator circuit 21 can comprise further passive elements, such as a capacitance 27 and a resistance 26. Furthermore, the gyrator circuit 21 can comprise a feedback path.

Thus, compared to a conventional bias tee circuit, the coil (or a part thereof in case of a multi-stage bias-tee) is replaced by an active circuit. The bias circuit 20 can replicate the general function of a coil via the gyrator circuit 21. In addition, the biasing circuit 20 can be used for regulating the DC supply voltage similar to a linear regulator. An advantage of using this biasing circuit 20 is the fact that the output resistance of the gyrator circuit 21 is very low. Furthermore, the biasing circuit 20 can operate at low frequencies of less than 100 MHz of an RF signal to be amplified, allowing the amplifier 13 to operate over a wide frequency range. Furthermore, the gyrator circuit 21 requires less space and exhibits less parasitic effects than a conventional coil, in particular a coil for low frequencies.

In a further example, the first receiver circuit 14a, which receives an amplified signal from the amplifier 13, is an image free receiver circuit which is configured reduce the effect of unwanted signal frequencies (so-called “image frequencies) on its output signal. In general, a receiver circuit can generate an IF (intermediate frequency) signal from an RF signal (e.g., the stimulus or a test signal) received at its input by mixing said RF signal with the local oscillator LO signal. However, an unwanted signal at an image frequency of the RF signal could be mixed to the same intermediate frequency. The image frequency depends on the RF and the LO signal. The image-free receiver circuit can use different techniques to prevent such image frequency signals from affecting the generated IF signal.

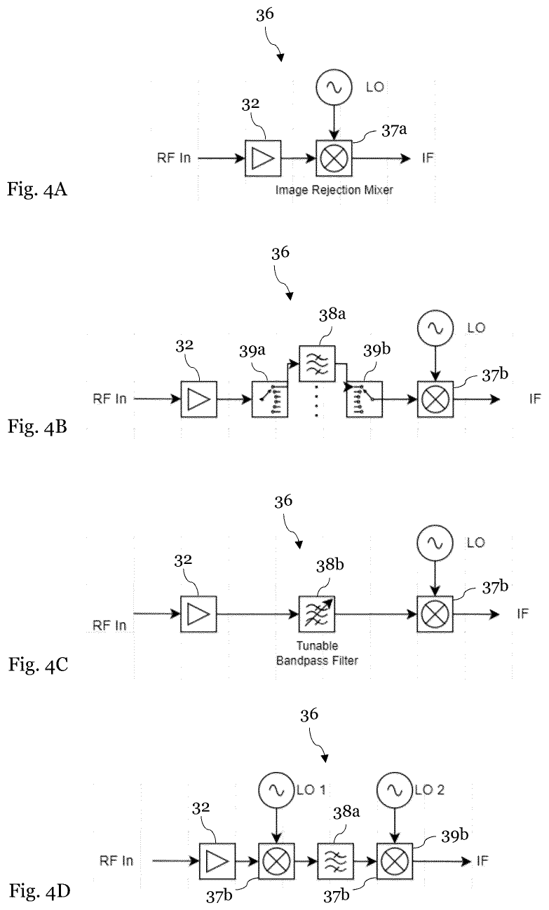

FIGS. 4A-4D show exemplary embodiments of the image-free receiver circuit. This image-free receiver circuit comprises a conversion unit 36 which is configured to convert an RF signal received at the input to an image-free IF signal.

The exemplary conversion unit 36 shown in FIG. 4A comprises an image rejection mixer 37a. This image rejection mixer 37a is a specific type of mixer which is configured to cancel out the unwanted mix products. For instance, the image rejection mixer 37a separates the LO signal from the local oscillator LO in two separate LO signals of different phase.

The exemplary conversion unit 36 shown in FIG. 4B comprises a filter bank with a number of bandpass filters 38a that can be selectively switched in the signal path between an LNA 32 and a mixer 37b using two switching units 39a, 39b.

The exemplary conversion unit 36 shown in FIG. 4C comprises a tunable bandpass filter 38 whose passband can be adjusted (tuned) to different frequency ranges. Similar to the filter bank this allows setting of the passband to a desired frequency range of a (wanted) RF signal while rejecting other signals (e.g., an image frequency signal).

The exemplary conversion unit 36 shown in FIG. 4D comprises multiple conversion stages, each conversion stage having a mixer 37b and a local oscillator LO1, LO2. A bandpass filter 38a can be arranged between the two stages. In this way, a multiple conversion receiver can be formed which suppresses unwanted image frequency components in the resulting IF signal.

For instance, the first receiver circuit 14a of the system 10 shown in FIG. 1 is an image-free receiver circuit according to any one of FIGS. 4A to 4D.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired and advantageous for any given or particular application.

1. A test and/or measurement system for measuring a noise figure of a device-under-test, DUT, comprising:
a test port arranged for being connected to a port of the DUT;
an interface unit comprising and amplifier; and
a first receiver circuit;
wherein, if the test and/or measurement system is operated in a noise figure measurement mode, an input port of the amplifier is electrically connected to the test port and an output port of the amplifier is electrically connected to the first receiver circuit;
wherein the interface unit further comprises a biasing circuit which is electrically connected to the output port of the amplifier and is configured to provide a biasing current and/or voltage for the amplifier during operation;
wherein the biasing circuit comprises at least one gyrator circuit.

2. The test and/or measurement system of claim 1,
wherein the at least one gyrator circuit is configured to provide an impedance of more than 100 μH, 200 μH, 500 μH, 800 μH, 1 mH, 2 mH, 4 mH, 8 mH, 30 mH, 60 mH, 100 mH, or 200 mH to the output port of the amplifier.

3. The test and/or measurement system of claim 1,
wherein the gyrator circuit comprises an input port which is configured to receive a DC bias voltage.

4. The test and/or measurement system of claim 1,
wherein the gyrator circuit is an active gyrator circuit comprising at least one operational amplifier.

5. The test and/or measurement system of claim 1,
wherein the bias circuit comprises at least one of the following passive elements: an inductance, a capacitance, and a resistance;
wherein the at least one passive element is electrically connected between the at least one gyrator circuit and the output port of the amplifier.

6. The test and/or measurement system of claim 1,
wherein the first receiver circuit comprises at least one of the following elements: an amplifier unit, a filter unit, and a mixing unit.

7. The test and/or measurement system of claim 1, further comprising:
a base unit which comprises a first ADC unit, wherein the first ADC unit is electrically connected to the first receiver circuit.

8. The test and/or measurement system of claim 7,
wherein the base unit and the interface unit are arranged in the same housing or in separate housings.

9. The test and/or measurement system of claim 1, further comprising:
a frontend unit, wherein the test port is arranged on the frontend unit.

10. The test and/or measurement system of claim 9,
wherein the frontend unit and the interface unit are arranged in the same housing or in separate housings.

11. The test and/or measurement system of claim 1,
wherein the interface unit comprises a switching unit which is configured to connect the test port to the amplifier if the test and/or measurement system operates in the noise figure measurement mode.

12. The test and/or measurement system of claim 11, further comprising:
a second receiver circuit; a directive element; and a signal source configured to generate a test signal;
wherein the directive element is electrically connected to the switching unit, the signal source, the first receiver circuit and the second receiver circuit, and
wherein the test and/or measurement system is operable in an S-parameter measurement mode.

13. The test and/or measurement system of claim 12,
wherein, if the test and/or measurement system is operated in the S-parameter measurement mode, the switching unit is configured to electrically connect the test port to the directive element; and the directive element is configured to forward the test signal after being transmitted by the DUT and received via the test port to the second or the first receiver circuit.

14. The test and/or measurement system of claim 12,
wherein, if the test and/or measurement system is operated in the S-parameter measurement mode, the switching unit is configured to electrically connect the test port to the directive element; and the directive element is configured to: forward a first part of the test signal to the test port; a second part of the test signal to one of the first or the second receiver circuit, and a reflection of the first part of the test signal from the DUT which is received via the test port to the other one of the first or the second receiver circuit.

15. The test and/or measurement system of claim 12,
wherein the first and/or the second receiver circuit are arranged in the interface unit.

16. The test and/or measurement system of claim 7,
wherein the base unit comprises a second ADC unit, wherein the second ADC unit is electrically connected to the second receiver circuit.
